(19) United States
(12) Patent Application Publication
(10) Pub. No.: US 2025/0346991 A1
(43) Pub. Date: Nov. 13, 2025

(54) SPUTTERING APPARATUS AND EVALUATION METHOD OF SPUTTERING TARGET

(71) Applicant: Japan Display Inc., Tokyo (JP)

(72) Inventors: Masanobu IKEDA, Tokyo (JP); Masumi NISHIMURA, Tokyo (JP)

(73) Assignee: Japan Display Inc., Tokyo (JP)

(21) Appl. No.: 19/270,548

(22) Filed: Jul. 16, 2025

Related U.S. Application Data
(63) Continuation of application No. PCT/JP2024/000283, filed on Jan. 10, 2024.

(30) Foreign Application Priority Data
Feb. 20, 2023 (JP) 2023-024493

(51) Int. Cl. C23C 14/34; C23C 14/50; C23C 14/54

(52) U.S. Cl. CPC C23C 14/3407; C23C 14/50; C23C 14/54

(57) ABSTRACT

A sputtering apparatus includes a target holder for holding a sputtering target, at least one light source for irradiating the sputtering target held by the target holder with light, and at least one detector. The at least one detector is arranged to detect at least one of reflected light and scattered light of the light at a surface of the sputtering target.

This application is a Continuation of International Patent Application No. PCT/JP2024/000283, filed on Jan. 10, 2024, which claims the benefit of priority to Japanese Patent Application No. 2023-024493, filed on Feb. 20, 2023, the entire contents of which are incorporated herein by reference.

### FIELD

An embodiment of the present invention relates to a sputtering apparatus having a function for evaluating characteristics and states of a sputtering target and a method for evaluating a sputtering target.

### BACKGROUND

Transistors, capacitor elements, and the like which structure semiconductor devices are fabricated by stacking thin films of appropriately patterned conductors, insulators, and semiconductors. One of the typical methods to fabricate these thin films is sputtering. Recently, it has been known that highly crystalline thin films can be fabricated by sputtering nitrides of Group 13 elements such as gallium nitride (GaN) and indium nitride (InN) which are expected to be wide-gap semiconductors (see, International Patent Publication No. 2020/075599, Japanese Laid-Open Patent Publications No. 2008-270749 and 2019-147976, International Patent Publication No. 2022/070922, and Japanese Laid-Open Patent Publication No. 2017-179529).

### SUMMARY

An embodiment of the present invention is a sputtering apparatus. The sputtering apparatus includes a target holder for holding a sputtering target, at least one light source for irradiating the sputtering target held by the target holder with light, and at least one detector. The at least one detector is arranged to detect at least one of reflected light and scattered light of the light at a surface of the sputtering target.

An embodiment of the present invention is an evaluation method of a sputtering target. The evaluation method includes irradiating the sputtering target with light from at least one light source and detecting at least reflected light and scattered light of the light at a surface of the sputtering target.

### BRIEF DESCRIPTION OF DRAWINGS

FIG. 1 is a schematic drawing of a sputtering apparatus according to an embodiment of the present application.

FIG. 2 is a schematic drawing of a sputtering apparatus according to an embodiment of the present application.

FIG. 3 is a schematic drawing of a sputtering apparatus according to an embodiment of the present application.

FIG. 4 is a schematic drawing of a sputtering apparatus according to an embodiment of the present application.

FIG. 5 is a schematic drawing of a sputtering apparatus according to an embodiment of the present application.

FIG. 6 is a flow chart including an example of an evaluation method of a sputtering target according to an embodiment of the present application.

FIG. 7 is a schematic drawing for explaining an evaluation method of a sputtering target according to an embodiment of the present application.

FIG. 8 is a flow chart including an example of an evaluation method of a sputtering target according to an embodiment of the present application.

FIG. 9 is a schematic cross-sectional view of a light-emitting diode manufactured using a sputtering apparatus according to an embodiment of the present application.

FIG. 10A is a schematic cross-sectional view of a transistor manufactured using a sputtering apparatus according to an embodiment of the present application.

FIG. 10B is a schematic cross-sectional view of a transistor manufactured using a sputtering apparatus according to an embodiment of the present application.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate. The reference number is used when plural structures which are the same as or similar to each other are collectively represented, while a hyphen and a natural number are further used when these structures are independently represented.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure. In addition, a mode expressed by this expression includes a mode where a structure is not in contact with other structures.

Hereinafter, a sputtering apparatus according to the present embodiment and a method of evaluating a sputtering target using the sputtering apparatus are explained.

### 1. Sputtering Apparatus

### (1) Structure

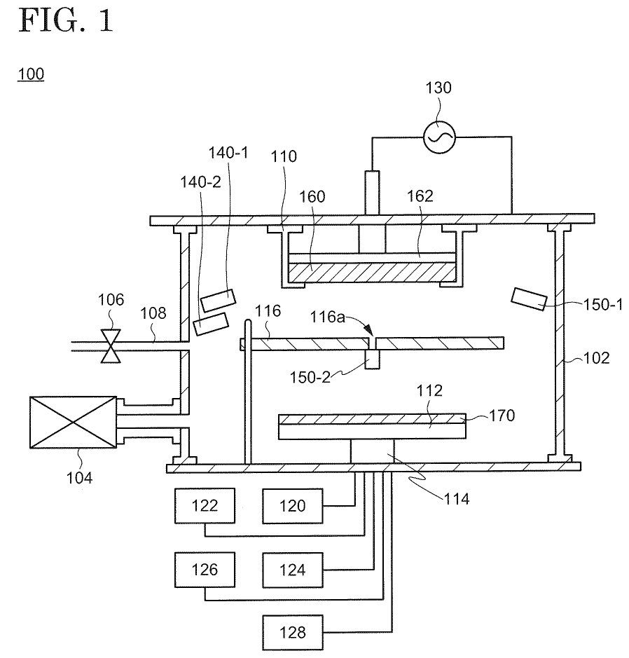

FIG. 1 shows a schematic view including a cross section of a sputtering apparatus 100 according to the present embodiment. The sputtering apparatus 100 is a deposition apparatus having a function to deposit thin films of conductors, semiconductors, or insulators over a substrate by a sputtering method. The sputtering apparatus 100 has a chamber 102 to provide a field for the collision of high-speed ions with a sputtering target and the deposition of target atoms generated in the collision. The chamber 102 is connected to an exhaust device 104 for reducing the pressure in the chamber 102 and is further provided with one or a plurality of introduction pipes 108 and valves 106 for introducing sputtering gases such as argon, nitrogen, oxygen, and hydrogen into the chamber 102. A stage 112 for arranging a substrate 170 over which thin films are to be formed is provided at a lower portion of the chamber 102. Although not illustrated, an electrostatic chuck may be provided over the stage 112 to fix the substrate 170. The stage 112 may be connected, either directly or through a shaft 114, to a power supply 120 for supplying high frequency power to the stage 112, a heater power supply 122 for heating the stage 112, a power supply 124 for the electrostatic chuck, a controller 126 for controlling the temperature of a cooling medium circulated in the stage, a rotation-controlling device 128 for rotating the stage 112, and the like.

A target holder 110 for holding a backing plate 162 and a sputtering target 160 fixed to the backing plate 162 and containing a material to be deposited is disposed at an upper portion of the chamber 102. A high-frequency power supply 130 is connected to the chamber 102 to apply an AC voltage to the sputtering target 160 via the backing plate 162, allowing the generation of plasma in the chamber 102 by the high-frequency power supply 130. Note that a DC power supply or a pulse power supply may be used instead of the high-frequency power supply 130. Although not illustrated, a magnet may be arranged on a side of the backing plate 162 opposite to the sputtering target 160. Furthermore, a solenoid coil may be arranged to surround the space on the stage 112 side with respect to the sputtering target 160. Note that although one target holder 110 is provided in the chamber 102 in the example demonstrated in FIG. 1, the sputtering apparatus 100 may have a plurality of target holders 110.

A shutter 116 is further provided between the stage 112 and the target holder 110 in the chamber 102. The shutter 116 is provided to control the deposition of atoms sputtered from the sputtering target 160 during deposition. Hence, the shutter 116 is configured to take on an open state which allows the atoms sputtered from the sputtering target 160 to reach and deposit over the substrate 170 and a closed state which blocks the atoms sputtered from the sputtering target 160 and prohibits the deposition of the atoms. Ions of the sputtering gas accelerated by the plasma generated in the chamber 102 collide with the sputtering target 160, and the collision energy sputters the atoms of the sputtering target 160. The sputtered atoms fly to and are deposited over the substrate 170 placed over the stage 112 while the shutter 116 is open. This mechanism allows a thin film including the material contained in the sputtering target 160 to be formed over the substrate 170.

In the sputtering apparatus 100 shown in FIG. 1, the sputtering target 160 is arranged over the stage 112, and these components overlap each other in the vertical direction. However, the stage 112 may be arranged over the sputtering target 160 in the sputtering apparatus 100. Alternatively, the stage 112 and the sputtering target 160 may be arranged to horizontally overlap each other.

The sputtering apparatus 100 further includes at least one light source 140 and at least one detector 150. The at least one light source 140 may include a plurality of light sources (e.g., a first light source 140-1 and a second light source 140-2). A light source configured to emit visible light including a plurality of wavelengths with a wavelength difference of at least 50 nm or more may be used as the light source 140. Thus, a white-emissive light source or a light source configured to emit a plurality of monochromatic lights may be used as the light source 140.

A white-emissive light source is a light source providing light exhibiting a continuous spectrum over a range of 400 nm to 800 nm. A halogen lamp, a xenon lamp, a light-emitting diode configured to emit white light, or a combination of a red-emissive diode, a green-emissive diode, and a blue-emissive diode which each emit non-coherent light may be used as the white-emissive light source. Here, a red-emissive diode is configured to exhibit at least one emission peak between 650 nm and 800 nm, a green-emissive diode is configured to exhibit at least one emission peak between 500 nm and 650 nm, and a blue-emissive diode is configured to exhibit at least one emission peak between 400 nm and 500 nm, for example.

A light source configured to emit a plurality of monochromatic lights includes a combination of at least two selected from a red-emissive diode, a green-emissive diode, and a blue-emissive diode which can be independently operated. These light-emitting diodes may be each a light-emitting diode providing non-coherent light or a diode emitting laser light.

When the sputtering apparatus 100 has a plurality of light sources 140, a white-emissive light source such as a xenon lamp and a halogen lamp may be used as one of the light sources 140 (e.g., the first light source 140-1), while at least two selected from a red-emissive diode, a green-emissive diode, and a blue-emissive diode which can be independently operated may be used as the other of the light sources 140 (e.g., the second light source 140-2).

When the sputtering apparatus 100 has a plurality of target holders 110, at least one light source 140 may be arranged for each sputtering target 160 held by the respective target holder 110. Alternatively, a rotating or moving mechanism (not illustrated) may be provided to each of the holders holding the respective light sources 140, and the sputtering apparatus 100 may be configured so that each light source 140 can irradiate the plurality of sputtering targets 160 with light.

The detector 150 is a photodetector (sensor) having a function of detecting the light from the light source 140 reflected on the surface of the sputtering target 160 (reflected light) and/or scattered on the surface (scattered light). Thus, the detector 150 is configured to acquire a spectrum of the reflected light and/or the scattered light or to measure the intensity of the reflected light and/or the scattered light at a plurality of wavelengths. At least one detector 150 may include a plurality of detectors (e.g., a first detector 150-1 and a second detector 150-2). When the sputtering apparatus 100 includes two detectors 150, these detectors may be arranged such that the first detector 150-1 detects the reflected light and the second detector 150-2 detects the scattered light. When the sputtering apparatus 100 has a plurality of target holders 110, at least one detector 150 may be provided for each of the sputtering targets 160 held by the plurality of target holders 110, or a holder (not illustrated) holding each detector 150 may be provided with a rotating or moving mechanism, and the sputtering apparatus 100 may be configured so that each detector 150 is capable of detecting the light reflected and/or scattered on the plurality of sputtering targets 160.

Although not illustrated, a controlling device is connected to the detector 150 via a wiring, and the data obtained by the detector 150 is analyzed by the controlling device. The characteristics of the sputtering targets 160 are evaluated on the basis of the analysis results.

### (2) Arrangement of Components

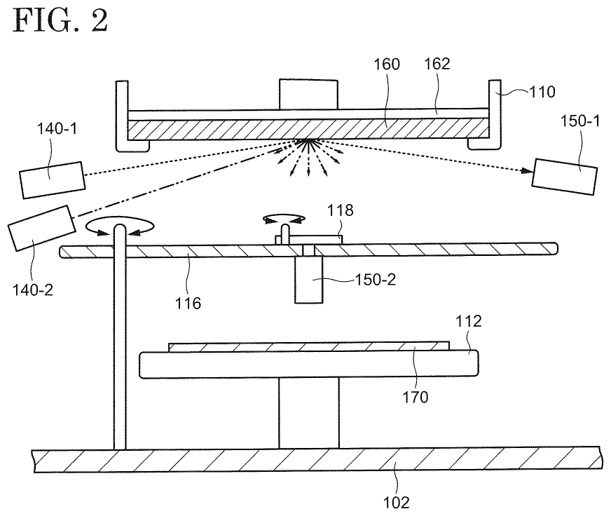

The arrangement of the light source 140, the detector 150, the target holder 110, and the shutter 116 is explained using FIG. 2. The light source 140 may be arranged at an arbitral position and angle (i.e., in an arbitral direction of the light emission) as long as the light is applied onto the sputtering target 160. However, it is preferable that the reflected light and/or the scattered light can be detected by the detector 150 whether the shutter 116 is in an open state or a closed state. Hence, the light source 140 is preferably arranged so that, when the shutter 116 is closed, the light passes through at least a part of the gap between the shutter 116 and the target holder 110 or at least a part of the gap between the shutter 116 and the sputtering target 160 and is applied onto the surface of the target holder 110 (a surface on an opposite side with respect to the backing plate 162) as shown in FIG. 2. In order to achieve such an arrangement, the light source 140 may be arranged so that the incident angle of the light to the sputtering target 160 is equal to or more than 60° and equal to or less than 85°, equal to or more than 70° and equal to or less than 85°, or equal to or more than 75° and equal to or less than 85°.

The detector 150 for detecting the reflected light (in this case, the first detector 150-1) is arranged so that the light from the light source 140 (in this case, the first light source 140-1) directly reflected on the surface of the sputtering target 160 is incident as shown by the dotted line in FIG. 2. The first detector 150-1 may be arranged at an arbitral position and angle (i.e., in an arbitral traveling direction of the reflected light) as long as this condition is satisfied. However, it is preferable that the reflected light can be detected whether the shutter 116 is open or closed. Thus, it is preferable to arrange the first detector 150-1 so that the reflected light enters the first detector 150-1 after passing through at least a part of the gap between the shutter 116 and the target holder 110 or at least a part of the gap between the shutter 116 and the sputtering target 160 as shown in FIG. 2.

The detector 150 for detecting the scattered light (the second detector 150-2 in the example shown in FIG. 2) is arranged so that the reflected light is not incident thereon and only the scattered light can be selectively detected. The arrangement of the second detector 150-2 is arbitrary as long as this condition is satisfied, and the detector 150 may be arranged so that the shutter 116 is positioned between the second detector 150-2 and the target holder 110, for example. In this case, the shutter 116 is provided with a through hole 116a (see FIG. 1), and the scattered light is incident on the second detector 150-2 through the through hole 116a (see two-dot chain line in FIG. 2). Note that a second shutter 118 may be provided to the shutter 116 to open and close the through-hole 116a in order to prevent contamination by the materials sputtered from the sputtering target 160 during pre-sputtering described below.

### (3) Modified Examples

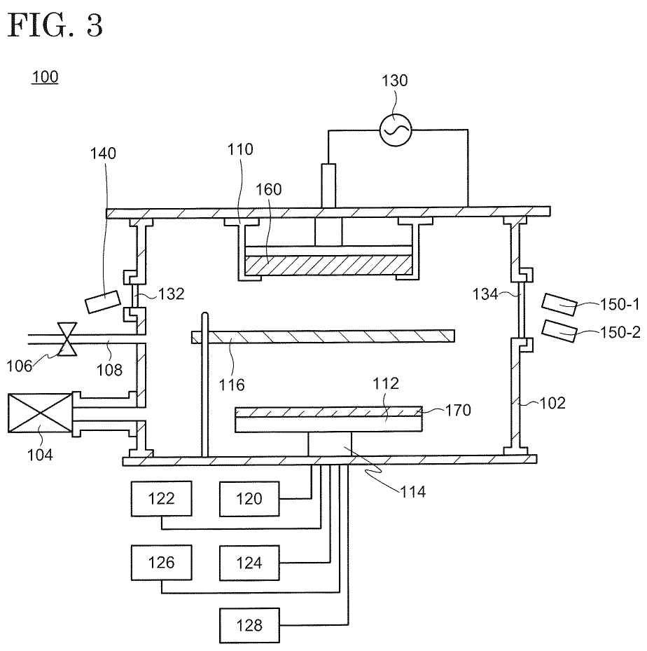

In the examples shown in FIG. 1 and FIG. 2, the light source 140 and the detector 150 are arranged within the chamber 102. However, all or a part of the light source 140 and the detector 150 may be arranged outside the chamber 102 as shown in FIG. 3. In this case, windows 132 and 134 may be provided on the sidewalls of the chamber 102. The windows 132 and 134 are composed of a material capable of transmitting visible light, such as quartz, for example. The light from the light source 140 may be applied onto the surface of the sputtering target 160 through the window 132, and the reflected light and/or the scattered light thereof may be detected by the detector 150 through the window 134.

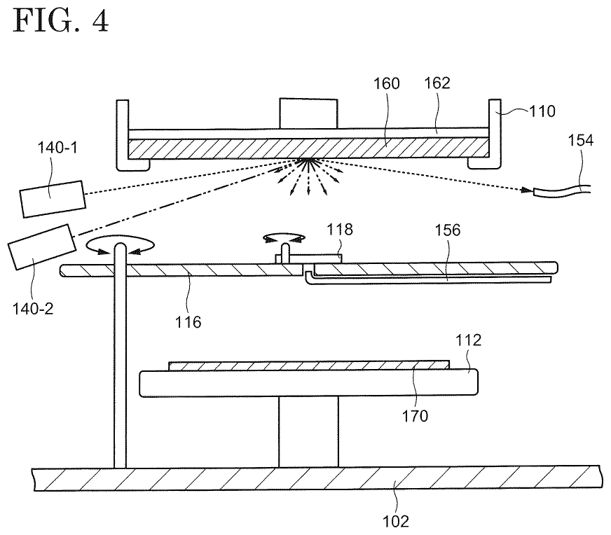

Alternatively, the reflected light and/or the scattered light may be introduced into the detector 150 via a bundle fiber containing one or a plurality of optical fibers. For example, a bundle fiber 154 is arranged in the chamber 102 so that the reflected light is incident as shown in FIG. 4. The detector 150 for detecting the reflected light is connected to an end of the bundle fiber 154 and is arranged inside or outside the chamber 102. Similarly, a bundle fiber 156 is arranged so that the scattered light passing through the through hole 116a of the shutter 116 is incident on one end of the bundle fiber 156. The detector 150 for detecting the scattered light is connected to the other end of the bundle fiber 156 and is arranged inside or outside the chamber 102.

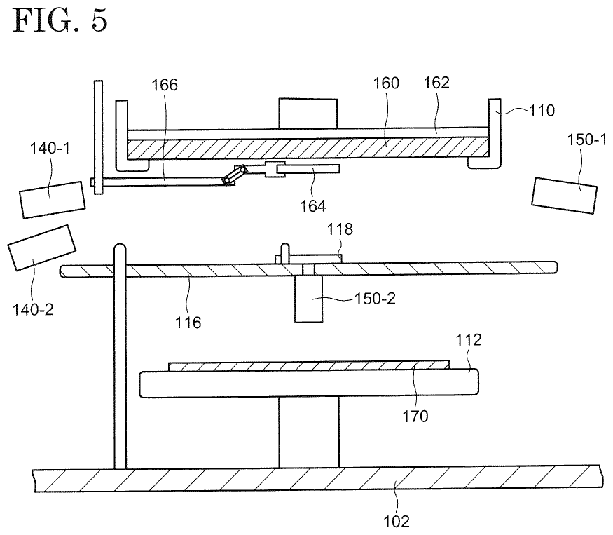

Furthermore, the sputter apparatus 100 may further include, as optional components, a reference 164 for acquiring data for correction (described below) and a moving mechanism 166 for moving the reference 164 (FIG. 5). The moving mechanism 166 is configured so that the reference 164 is positioned so as not to interfere with the flight of the sputtered materials during deposition and the surface of the reference 164 is positioned on the light path of the light source 140 during data acquisition for baseline correction. In addition, the moving mechanism 166 is configured to move the reference 164 so that the reflected light is incident on one detector 150 (here, the first detector 150-1) when detecting the reflected light. The movement mechanism 166 is also configured to move the reference 164 so that the reflected light does not enter the first detector 150-1 but the scattered light enters the other detector 150 (here, the second detector 150-2) when detecting the scattered light.

### 2. Evaluation Method of Sputtering Targets Using Sputtering Apparatus

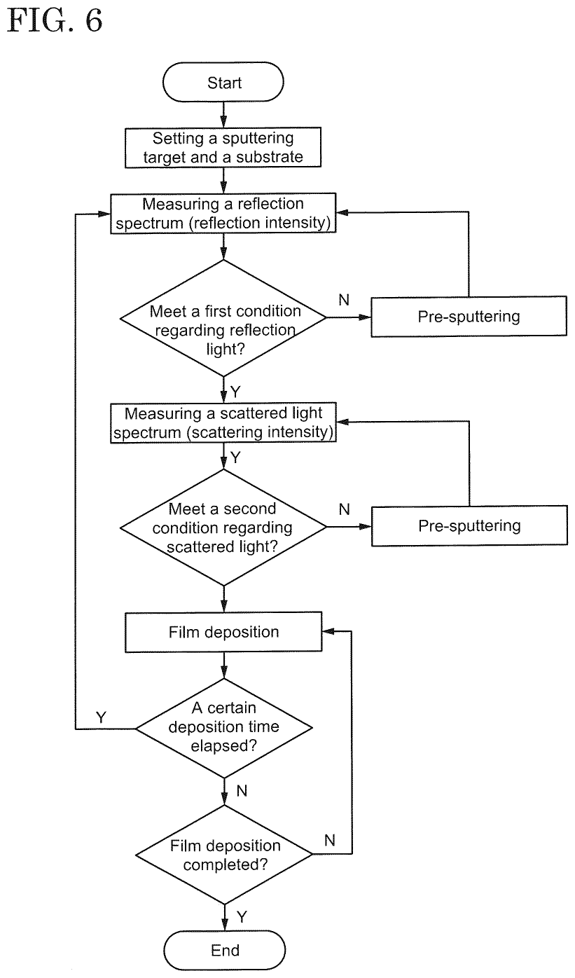

Hereinafter, a method of evaluating the characteristics of the sputtering target 160 using the aforementioned sputtering apparatus 100 is explained using the flowchart in FIG. 6. In this evaluation method, at least one of the reflected light and the scattered light from the light source 140 respectively reflected and scattered at the surface of the sputtering target 160 is detected by the detector 150, by which the composition (especially, composition at the surface) and the surface conditions (especially, surface irregularity) of the sputtering target 160 can be evaluated on the basis of the analysis results. Hereinafter, an explanation is provided using an example in which the first light source 140-1 and the second light source 140-2 are respectively used as light sources for the reflected light and the scattered light, and the reflected light of the light from the first light source 140-1 and the scattered light of the light from the second light source 140-2 are respectively detected by the first detector 150-1 and the second detector 150-2. Although there is no restriction on the order of detection of the reflected light and the scattered light, an example in which the reflected light is detected and then the scattered light is detected is used for convenience. Note that a single detector may be used to detect either the reflected light or the scattered light. Alternatively, the reflected light may be detected after the scattered light is detected. Alternatively, one light source 140 and two detectors 150 may be used to simultaneously detect both scattered light and reflected light.

### (1) Setup of Sputtering Target and Substrate

First, the sputtering target 160 is set on the target holder 110 of the sputtering apparatus 100. There are no restrictions on the materials contained in the target. For example, a metal (0-valent metal) such as aluminum, cobalt, chromium, molybdenum, niobium, titanium, tungsten, zinc, silver, gold, iron, and iridium, an alloy thereof, an oxide such as aluminum oxide, copper oxide, chromium oxide, cesium oxide, magnesium oxide, titanium oxide, tungsten oxide, and strontium titanate, a nitride such as aluminum nitride, chromium nitride, and silicon nitride, a non-metallic element such as silicon, boron, carbon, and germanium, and a compound semiconductor are exemplified. A compound semiconductor includes a gallium phosphide-based compound semiconductor such as gallium phosphide, aluminum indium gallium phosphide, and indium gallium phosphide arsenide, an indium-based compound semiconductor such as indium phosphide, and silicon carbide in addition to a gallium nitride-based compound semiconductor such as gallium nitride, aluminum gallium nitride, and indium gallium nitride. The sputtering target may contain a dopant such as silicon, germanium, magnesium, zinc, cadmium, and beryllium.

Furthermore, the substrate 170 is set over the stage 112. There are no restrictions on the substrate 170, and a glass substrate and a plastic substrate can be used in addition to a silicon substrate, a sapphire substrate, and a quartz substrate, for example. The substrate 170 may be a single crystalline substrate or an amorphous substrate. A material contained in a plastic substrate includes a polymer such as a polyimide, a polyamide, and a polycarbonate. The substrate 170 may be flexible.

Although not illustrated in FIG. 6, after setting the sputtering target 160, pre-sputtering may be performed on the sputtering target 160 as an optional step. Pre-sputtering is a step to subject the sputtering target 160 to sputtering in a state where the shutter 116 is closed, by which a part of the surface of the sputtering target 160 can be removed. The conditions at this time may be the same as those for film deposition over the substrate 170. Alternatively, when argon and other gases are simultaneously used during film deposition, pre-sputtering may be performed using only argon as the sputtering gas.

### (2) Measurement of Reflection Spectrum (Reflection Intensity) and Evaluation of Sputtering Target

When the sputtering target 160 is sputtered to deposit a film, the sputtering target 160 may gradually degrade. One of the reasons for degradation is a reaction with the sputtering gases (e.g., nitrogen radicals and oxygen radicals), which may result in nitridation or oxidation on the surface of the sputtering target 160 to change its composition (especially, composition at the surface). Alternatively, in the case of the sputtering target 160 containing a compound, the composition may gradually change if the speeds at which atoms are sputtered (sputtering rate) are different. When such compositional changes occur, the composition of the film deposited over the substrate 170 may change, which may result in changes in properties such as crystallinity, a band gap, conductivity, and carrier mobility.

Since the sputtering targets 160 are fabricated to have a specific composition for its application, they exhibit a reflection spectrum specific to their compositions. However, when the sputtering target 160 degrades and undergoes compositional changes, the color thereof, that is, the reflection spectrum thereof changes. Therefore, in this evaluation method, after the sputtering target 160 and the substrate 170 are set, the reflected light is measured, and the composition is monitored on the basis of the measurement results.

Specifically, light is emitted from the first light source 140-1 in a state in which no plasma is generated (e.g., the state where the high-frequency power source 130 is turned off), and the reflected light on the surface of the sputtering target 160 is detected by the first detector 150-1. At this time, the shutter 116 may be closed or opened. The data acquired by the first detector 150-1 is transmitted to the controlling device which is not illustrated, and the controlling device acquires the reflection spectrum or the reflection intensities (reflectances) at a plurality of wavelengths for characteristic evaluation (hereinafter, referred to as reference wavelengths). At least two reference wavelengths are selected so that the wavelength difference therebetween is 50 nm or more.

Next, the data acquired by the first detector 150-1 is used to compare the reflection intensities at the plurality of reference wavelengths and determine whether the comparison results satisfy certain conditions (first condition). More specifically, a plurality of reference wavelengths (λ₁, λ₂) is set in the visible light region, and whether or not the reflection intensity ratio at the reference wavelengths is within a certain range is judged. If the intensity ratio is within a certain range, it is judged that the composition of the sputtering target 160 has not significantly changed and the sputtering target 160 can be used for subsequent film deposition. Conversely, if the intensity ratio is outside a certain range, it is judged that the composition of the sputtering target 160 has changed and does not meet the criteria, and replacement of the sputtering target 160, change of the sputtering conditions, or pre-sputtering is performed as described below.

The first condition can be expressed by the following general formula, where λ₁ and λ₂ are respectively the first reference wavelength and the second reference wavelength, Iᵣ(λ₁) and Iᵣ(λ₂) are respectively the reflection intensities at the first reference wavelength λ₁ and the second reference wavelength λ₂, and Thᵣ₁ and Thᵣ₂ are respectively a minimum threshold value and a maximum threshold value.

$${Th}_{r 1} < \frac{{I}_{r} ( {λ}_{1} )}{{I}_{r} ( {λ}_{2} )} < {Th}_{r 2}$$

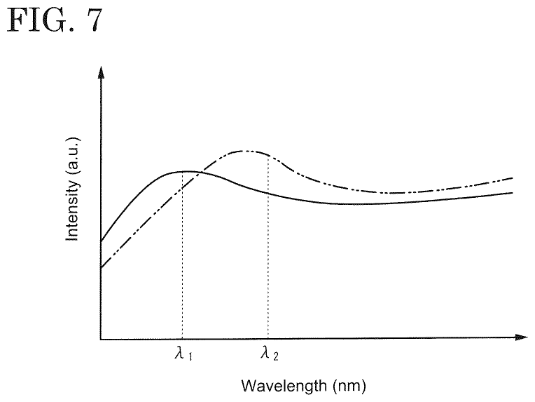

As the first reference wavelength λ₁ and the second reference wavelength λ₂, wavelengths at which the reflection spectrum intensities significantly change with compositional change may be selected. For example, when the reflection spectrum of the sputtering target 160 shown by the solid line changes to the reflection spectrum shown by the two-dot chain line due to the compositional change as schematically shown in FIG. 7, the wavelength exhibiting the maximum peak shifts. In such a case, the maximum peak wavelengths of the former and the latter or their vicinities may be selected as the first reference wavelength λ₁ and the second reference wavelength λ₂. For example, when the sputtering target 160 contains gallium nitride, the first reference wavelength λ₁ may be selected from a range equal to or longer than 500 nm and equal to or shorter than 800 nm, and a typical example is 570 nm. Meanwhile, the second reference wavelength λ₂ may be selected from a range equal to or longer than 400 nm and equal to or shorter than 500 nm, and a typical example is 440 nm. The minimum threshold value Thᵣ₁ and the maximum threshold value Thᵣ₂ may also be determined as appropriate on the basis of the reflection spectrum of the sputtering target 160 in an undegraded state. For example, when the sputtering target 160 contains gallium nitride, the minimum threshold value Thᵣ₁ may be selected from a range equal to or more then 0.75 and equal to or less than 1.0 and is typically 0.85. Meanwhile, the maximum threshold value Thᵣ₂ may be selected from a range equal to or more then 1.1 and equal to or less than 1.3 and is typically 1.25. Note that the number of reference wavelengths is not limited to two, and three or more reference wavelengths may be selected. In this case, the first condition may be defined for each of the three combinations of the intensity ratios.

### (3) Measurement of Scattered Light Spectrum (Scattering Intensity) and Evaluation of Sputtering Target

Degradation of the sputtering target 160 occurs not only due to the compositional change, but also due to generation of unevenness on the surface. When unevenness above a certain level occurs on the surface, abnormal discharge tends to occur, which may cause damage to the formed film. Hence, this evaluation method uses the scattered light to evaluate the surface state of the sputtering target 160.

Specifically, light is emitted from the second light source 140-2 in a state where no plasma is generated, and the scattered light on the surface of the sputtering target 160 is detected by the second detector 150-2. At this time, the shutter 116 may be closed or opened. However, when the scattered light is detected from the through-hole 116a, the light irradiation and the detection of the scattered light are performed in a state where the shutter 116 closed. The data acquired by the second detector 150-2 is also transmitted to the controlling device which is not illustrated, and the scattered light spectrum or the scattered intensities at the plurality of reference wavelengths are measured by the controlling device.

Next, the data acquired by the second detector 150-2 is used to compare the scattering intensities at the reference wavelengths, and whether or not the comparison results meet certain conditions (the second condition) is judged. When the unevenness of the surface of the sputtering target 160 is small, i.e., when the difference in height of the unevenness is smaller than the wavelength of the light, the light from the second light source 140-2 is Rayleigh-scattered on the surface of the sputtering target 160. The Rayleigh scattering is proportional to the fourth power of the inverse of the wavelength (i.e., inversely proportional to the fourth power of the wavelength). Therefore, the Rayleigh scattering is highly wavelength dependent, and the scattering intensity increases with decreasing wavelength of the light from the second light source 140-2. On the other hand, when the unevenness of the surface of the sputtering target 160 increases, and the difference in height of the unevenness becomes equal to or greater than the wavelength of the light, the light from the second light source 140-2 is Mie-scattered on the surface of the sputtering target 160. Since the Mie scattering has a small wavelength dependence, the dependence of the scattering intensity at each wavelength on the wavelength of the light from the second light source 140-2 is small.

The characteristic differences between the Rayleigh scattering and the Mie scattering are used to evaluate the surface state of the sputtering target 160. Specifically, two or more reference wavelengths are used in the visible light region, and whether or not the intensity ratio of the scattered light at the reference wavelengths exceeds a certain value (threshold value) is judged. When the threshold value exceeds a certain value (i.e., when the wavelength dependence of the intensity of the scattered light is high), the scattering is dominated by the Rayleigh scattering, and the unevenness of the sputtering target 160 is judged to be small. Therefore, it is judged that the sputtering target 160 meets the criteria and can be used in the subsequent film deposition. Conversely, when the threshold value is equal to or lower than a certain value (i.e., when the wavelength dependence of the intensity of scattered light is small), it is judged that the scattering is dominated by the Mie scattering and the unevenness of the sputtering target 160 does not meet the criteria. In this case, the sputtering target 160 is replaced, the sputtering conditions are changed, or the pre-sputtering is performed as described below.

In the case of using two reference wavelengths, the second condition can be expressed by the following general formula, where λ₁ and λ₂ are respectively the first reference wavelength and the second reference wavelength (provided that λ₁<λ₂), Iₛ(λ₁) and Iₛ(λ₂) are respectively the scattering intensities at the first wavelength λ₁ and the second reference λ₂, and Thₛ₁ is a first threshold value.

$${Th}_{s 1} < \frac{{I}_{s} ( {λ}_{1} )}{{I}_{s} ( {λ}_{2} )}$$

The first reference wavelength λ₁ and the second reference wavelength λ₂ may be selected as appropriate from the visible light range, and the former may be selected from the range equal to or longer than 400 nm and equal to or shorter than 600 nm, while the latter may be selected from the range equal to or longer than 600 nm and equal to or shorter than 800 nm (provided that λ1<λ₂). When three reference wavelengths are used, the first reference wavelength λ₁ may be selected from the range equal to or longer than 400 nm and equal to or shorter than 500 nm, the second reference wavelength λ₂ may be selected from the range equal to or longer than 500 nm and equal to or shorter than 600 nm, and the third reference wavelength λ₃ may be selected from the range equal to or longer than 600 nm and equal to or shorter than 800 nm. (provided that λ₁<λ₂<λ₃). For example, when the sputtering target 160 contains gallium nitride, the typical first reference wavelength λ₁, second reference wavelength λ₂, and third reference wavelength λ₃ are respectively 440 nm, 530 nm, and 640 nm. When three reference wavelengths are used, the following general formula is added to the second condition in addition to the aforementioned general formula. Here, Iₛ(λ₃) is the scattering intensity at the third reference wavelength λ₃, and Thₛ₂ is a second threshold value. The first threshold value Thᵣ₁ and the second threshold value Thᵣ₂ may also be determined as appropriate on the basis of the original scattering spectrum of the sputtering target 160 or the original scattering intensities at the reference wavelengths. For example, when the sputtering target 160 contains gallium nitride, the first threshold value Thᵣ₁ and the second threshold value Thᵣ₂ may be selected from a range equal to or more than 1.0 and equal to or less than 1.2 and are typically 1.1. Note that, in the second condition, the maximum value of the ratio of the scattering intensity Iₛ(λ₁) at the first reference wavelength λ₁ with respect to the scattering intensity Iₛ(λ₂) at the second reference wavelength λ₂ and the maximum value of the ratio of the scattering intensity Iₛ(λ₁) at the first reference wavelength λ₁ with respect to the scattering intensity Iₛ(λ₃) at the third reference wavelength λ₃ are, for example, more than 1.1 and equal to or less than 1.4 and are typically 1.3.

$${Th}_{s 2} < \frac{{I}_{s} ( {λ}_{1} )}{{I}_{s} ( {λ}_{3} )}$$

### (4) Pre-Sputtering

If the first condition described above is not satisfied, pre-sputtering may be performed to sputter a part of the atoms at the surface and remove a part of the surface of the sputtering target 160. After that, the characteristic evaluation of the sputtering target 160 is performed again using the reflected light.

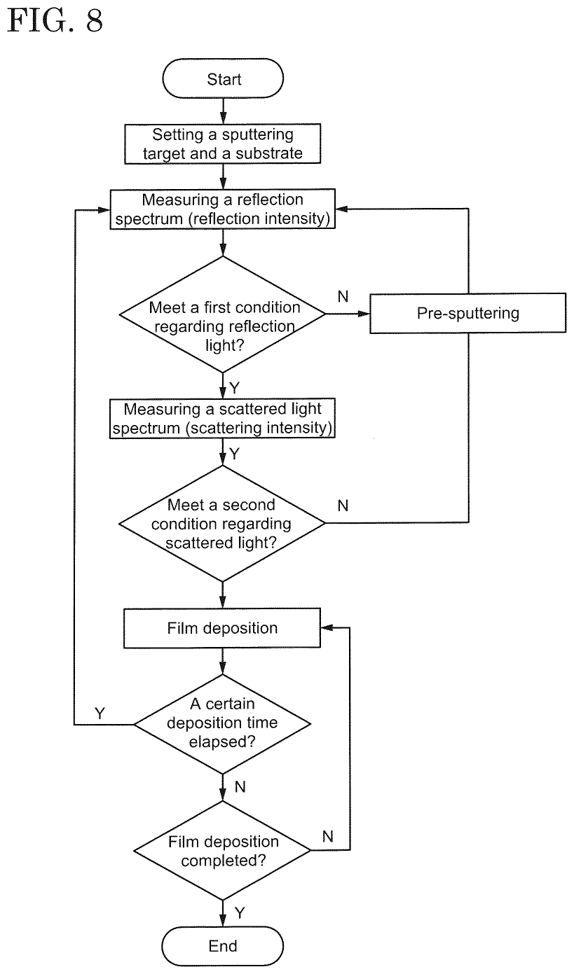

Similarly, when the second condition described above is not satisfied, pre-sputtering may be performed to sputter a part of the atoms on the surface and remove a part of the surface of the sputtering target 160. After that, the characteristic evaluation of the sputtering target 160 is performed again using the scattered light. Alternatively, the characteristic evaluation using the reflected light may be performed again after pre-sputtering as shown in FIG. 8.

Although not illustrated in FIG. 6 and FIG. 8, when the first condition and/or the second condition are not satisfied even after repeating pre-sputtering, pre-sputtering may be performed under different conditions. For example, the acceleration energy of the sputtering gas is changed, or the sputtering gas is changed (e.g., sputtering using argon gas). When the first condition and/or the second condition is not satisfied even after repeating pre-sputtering, the sputtering target 160 may be replaced.

### (5) Film Deposition

When the first condition and the second condition are satisfied, the shutter 116 is opened to perform film deposition. When the deposition time reaches a certain time, the sputtering target 160 may be deteriorated. Thus, the characteristic evaluation using the reflected light and/or the scattered light may be performed again as shown in FIG. 6 and the like. When the film deposition is completed, the series of deposition processes including the present evaluation method is completed.

### (6) Correction

In this evaluation method, the data acquired by the detector 150 (i.e., the reflection spectrum, the scattered light spectrum, or the reflection intensities or the scattering intensities at the reference wavelengths) may be directly used. However, data correction may be performed using the reference 164 at this time. For example, a sputtering target or a portion thereof which has a surface unevenness below a certain level and has a composition identical or substantially identical to the composition of the film to be formed may be used as the reference 164. The surface unevenness of the reference 164 may be evaluated, for example, by atomic force microscopy (AFM) or the like. The composition of the reference 164 may be determined by, for example, secondary ion mass spectrometry (SIMS), an energy dispersive X-ray spectrophotometer (EDX) mounted on an electron microscope, or the like.

The reference 164 is arranged in the light path of the light source 140 using the moving mechanism 166 (see FIG. 5), and the reflected light or the scattered light is acquired by the detector 150 to obtain the reflection spectrum or the scattered light spectrum as a baseline or obtain the reflection intensities or the scattering intensities at the reference wavelengths as reference values. The spectrum of the sputtering target 160 or the reflection intensities or the scattering intensities at the reference wavelengths may be obtained by subtracting the baseline from the spectrum obtained using the sputtering target 160 to be evaluated or by subtracting the reference values from the reflection intensities or the scattering intensities of the sputtering target 160.

The reference 164 is not limited to a sputtering target and may be a film having a surface unevenness below a certain level and identical or substantially identical composition to that of the film to be formed. Alternatively, a thin film of a metal such as aluminum and silver formed over a glass substrate, a silicon substrate, a sapphire substrate, or a quartz substrate may be used as the reference 164.

As described above, in this evaluation method, light is applied from the light source 140 onto the surface of the sputtering target 160, and the reflected light and/or the scattered light is used to evaluate the characteristics of the sputtering target 160. Therefore, it is possible to evaluate the characteristics of the sputtering target 160 without destroying the sputtering target 160. In addition, since there is no need to release the depressurization in the chamber 102 or eject the sputtering target 160 from the chamber 102, the characteristic evaluation can be performed simply by temporarily interrupting the sputtering process even when forming films over a plurality of substrates 170 in succession. Therefore, sputtering deposition can be performed continuously while always maintaining the characteristics of the sputtering target 160, especially the ideal composition and surface state, without placing a large burden on the process.

### 3. Application

The aforementioned sputtering apparatus 100 and the evaluation method of the sputtering targets 160 using the sputtering apparatus 100 can be applied to the manufacture of a variety of semiconductor devices. As the semiconductor devices, light-emitting diodes and transistors are represented.

### (1) Light-Emitting Diode

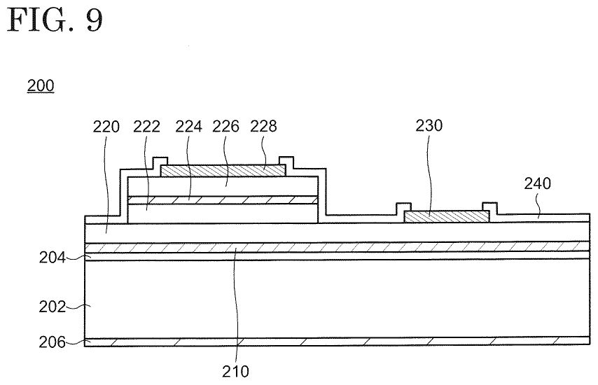

A schematic cross-sectional view of an example of a light-emitting diode 200 manufactured using the sputtering apparatus 100 is shown in FIG. 9. The light-emitting diode 200 has a substrate 202 and further includes a gallium nitride layer 220 over the substrate 202 through a buffer layer 210. The light-emitting diode 200 further includes, over the gallium nitride layer 220, a laminate containing an n-type cladding layer 222, a p-type cladding layer 226, and an emission layer 224 sandwiched between the n-type cladding layer 222 and the p-type cladding layer 226. In addition, the light-emitting diode 200 has an anode 228 and a cathode 230 respectively disposed over the p-type cladding layer 226 and the gallium nitride layer 220. The light-emitting diode 200 may further include an overcoat 204 between the substrate 202 and the buffer layer 210, an undercoat 206 under the substrate 202, and a protective film 240 over the anode 228 and the cathode 230 as optional components. Formation of a potential difference above the luminescence threshold voltage between the anode 228 and cathode 230 allows holes and electrons to be respectively injected from the anode 228 and cathode 230, and the holes and electrons are recombined in the emission layer 224 to produce light emission.

The substrate 202 is a component to support each of the components provided thereover and may include not only quartz, single-crystal silicon, or single-crystal sapphire but also amorphous glass such as alkali-free glass.

The overcoat 204, which is an optional component, is provided over the substrate 202 so as to be in contact with the substrate 202. The formation of the overcoat 204 prevents the diffusion of impurities such as alkali metal ions included in the substrate 202. The overcoat 204 may be a single film or a laminate of a plurality of films containing a silicon-containing inorganic compound such as silicon oxide and silicon nitride. The undercoat 206 suppresses elimination of water or the like from the substrate 202 under the high temperature conditions during the manufacture of the light-emitting diode 200, prevents impurities including oxygen from entering the gallium nitride layer 220, the n-type cladding layer 222, the emission layer 224, the p-type cladding layer 226, and the like, and further prevents warpage of the substrate 202 caused by the difference in thermal expansion coefficient between the substrate 202 and the gallium nitride layer 220. A film containing aluminum nitride, a film containing aluminum oxide, or a laminate thereof may be used as the undercoat 206.

The buffer layer 210 improves the adhesion between the substrate 202 and the gallium nitride layer 220 to prevent deformation (warpage) of the substrate 202 under the high temperature conditions during the manufacture of the light-emitting diode 200. Furthermore, the buffer layer 210 contributes to promotion of the crystallization of the gallium nitride layer 220 provided thereover in the c-axis direction 220. Therefore, the crystallinity of the gallium nitride layer 220 as well as that of each of the layers provided thereover can also be improved. As a result, the light-emitting diode 200 with excellent characteristics can be produced. The buffer layer 260 may be configured to include aluminum oxide, aluminum oxynitride, or the like. The buffer layer 210 may have a single-layer structure or a stacked-layer structure.

The gallium nitride layer 220 contains gallium nitride. Although p-type or n-type conductivity is imparted to gallium nitride by adding dopants, the gallium nitride layer 220 may be an undoped gallium nitride layer which does not contain any dopant. Alternatively, the gallium nitride layer 220 may include n-type gallium nitride containing a dopant imparting n-type conductivity (such as silicon and germanium) or p-type gallium nitride containing a dopant imparting p-type conductivity (such as magnesium, zinc, cadmium, and beryllium).

The n-type cladding layer 222, the emission layer 224, and the p-type cladding layer 226 are configured to emit visible light when holes and electrons respectively injected from the anode 228 and cathode 230 are recombined. The n-type cladding layer 222, the emission layer 224, and the p-type cladding layer 226 may each have a single-layer structure or a stacked-layer structure in which a plurality of layers is stacked. Although the n-type cladding layer 222, the emission layer 224, and the p-type cladding layer 226 are stacked in order from the substrate 202 side in the example demonstrated in FIG. 9, the reverse order of this sequence may be adopted. In this case, the gallium nitride layer 220 is configured to include undoped gallium nitride or p-type gallium nitride, over which the p-type cladding layer 226, the emission layer 224, and the n-type cladding layer 222 are fabricated.

The n-type cladding layer 222, the emission layer 224, and the p-type cladding layer 226 are each a semiconductor layer containing a Group 13 element and a Group 15 element. Specifically, a semiconductor containing aluminum, gallium, and/or indium as well as nitrogen, phosphorus, and/or arsenic are included in these layers. Gallium-based materials are represented as a typical semiconductor. Examples include gallium nitride-based materials such as gallium nitride, aluminum gallium nitride (AlGaN), and indium gallium nitride (InGaN) and gallium phosphide-based materials such as gallium phosphide (GaP) and aluminum indium gallium phosphorus (AlGaInP). The n-type cladding layer 222 and the p-type cladding layer 226 may further contain the dopants described above. The addition of dopants enables valence electron control of each layer and also enables band gap control. Note that the composition of the gallium nitride layer 220 and that of the layer provided over and in contact with the gallium nitride layer 220 (the n-type cladding layer 222 in the example shown in FIG. 9) may be identical.

The emission layer 224 may be a single-layer structure of indium gallium nitride or may have a quantum well structure, for example. A quantum well structure is a structure in which a plurality of layers having different band gaps and thicknesses approximately from 1 to 5 nm is alternatingly stacked and is exemplified by an alternating laminate of indium gallium nitride and gallium nitride, an alternating laminate of indium gallium phosphide arsenide (GaInAsP) and indium phosphide (InP), an alternating laminate of aluminum indium arsenide (AlInAs) and indium gallium arsenide (InGaAs), and the like.

The anode 228 and the cathode 230 inject holes and electrons into the p-type cladding layer 226 and n-type cladding layer 222, respectively. As the anode 228, a thin film of a metal such as palladium and gold, an alloy thereof, or a conductive oxide transmitting visible light, such as indium-tin mixed oxide (ITO) and indium-zinc mixed oxide (IZO), may be used, for example. A metal such as aluminum, titanium, gold, silver, and indium or an alloy thereof may be used as the cathode 230. Both the anode 228 and cathode 230 may have a single-layer structure or may be a laminate of a plurality of films having different compositions.

The protective film 240 is a component to prevent impurities such as oxygen and water from entering the light-emitting diode 200 and is composed of one or a plurality of films containing a silicon-containing inorganic compound such as silicon oxide and silicon nitride, for example. Openings are provided to the protective film 240 to expose the anode 228 and cathode 230, and wirings which are not illustrated are electrically connected to the anode 228 and cathode 230 using these openings.

The films of a variety of materials constituting the light-emitting diode 200 may be formed using a chemical vapor deposition (CVD) method or a sputtering method using the sputtering apparatus 100 described above. The film formation at a high temperature required by the epitaxial growth using a metal organic chemical vapor deposition (MOCVD) method is not required in the sputtering method, and the gallium nitride layer 220, the n-type cladding layer 222, the p-type cladding layer 226, the emission layer 224, and the like can be formed without deforming or damaging the substrate 200 even if the substrate 202 containing amorphous glass is used. Since the sputtering targets 160 including the materials contained in the films to be formed are used at this time, the use of the sputtering apparatus 100 allows the characteristics of the sputtering targets 160 to be evaluated at an arbitral time during the production of the light-emitting diode 200. Therefore, the sputtering targets 160 can always be maintained in an ideal state (e.g., with respect to composition and surface condition). As a result, the light-emitting diode 200 with excellent characteristics can be mass-produced without affecting the tact time.

### (2) Transistor

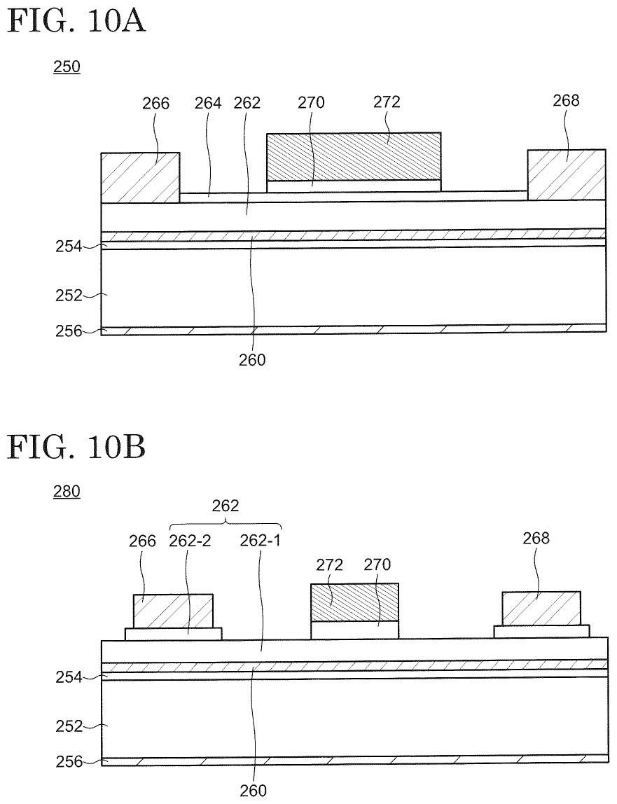

A schematic cross-sectional view of an example of a transistor 250 manufactured using the sputtering apparatus 100 is shown in FIG. 10A. The transistor 250 demonstrated in FIG. 10A is a high electron-mobility field-effect transistor and includes a substrate 252 as well as a buffer layer 260 and an active layer (also called an electron-travelling layer) 262 over the substrate 252. The transistor 250 further includes an electron-supplying layer 264 over the active layer 262 and a pair of terminals (first terminal 266 and second terminal 268) located over the active layer 262 and electrically connected to the active layer 262 and the electron-supplying layer 264. The first terminal 266 and the second terminal 268 may be in contact with the active layer 262 or may be in contact with the active layer 262 through the electron-supplying layer 264 although not illustrated. The transistor 250 further includes a gate electrode 272 in direct contact with the electron-supplying layer 264 or formed over the electron-supplying layer 264 through a gate insulating film 270 which is an optional component. Hereinafter, these components will be described below, but since the structures of the substrate 252, the overcoat 254, the undercoat 256, and the buffer layer 260 are the same as those of the corresponding components of the light-emitting diode 200 described above, the explanation thereof will be omitted.

The laminate of the active layer 262 and the electron-supplying layer 264 creates a source/drain current path when the transistor 250 is driven. The active layer 262 and the electron-supplying layer 264 contain a Group 13 element and a Group 15 element. For example, the active layer 262 and the electron-supplying layer 264 may respectively include undoped gallium nitride and n-type aluminum gallium nitride. Alternatively, the active layer 262 and the electron-supplying layer 264 may respectively include undoped gallium arsenide (GaAs) and n-type aluminum gallium arsenide (AlGaAs).

The buffer layer 260, the active layer 262, and the electron-supplying layer 264 may be formed with a sputtering method in the sputtering apparatus 100 described above. Therefore, film formation at the high temperatures required by epitaxial growth using a MOCVD method is not required, and these layers can be formed without deforming or damaging the substrate 252 even if the substrate 252 containing amorphous glass is used. The active layer 262 and the electron-supplying layer 264 are promoted to crystallize in the c-axis direction by the buffer layer 260 serving as a base film for these layers. Even if a sputtering method is used to form the active layer 262 and the electron-supplying layer 264, high c-axis orientation can be achieved in these layers. As a result, transistors with high field mobility can be produced.

The first terminal 266, the second terminal 268, and the gate electrode 272 include a metal such as aluminum, gold, silver, tantalum, molybdenum, titanium, and copper or an alloy containing one or a plurality of these metals. The gate insulating film 270, which is an optional component, includes a silicon-containing inorganic compound such as silicon oxide and silicon nitride or so-called high-k materials such as hafnium silicate, zirconium silicate, hafnium oxide, and zirconium oxide. These components may also be formed by a vacuum evaporation method, an electron beam evaporation method, or a CVD method. However, since the sputtering target 160 can always be maintained in an ideal condition by utilizing a sputtering method using the aforementioned sputtering apparatus 100, the transistors 250 with excellent characteristics can be mass-produced without affecting the tact time.

The transistor produced using the sputtering apparatus 100 may also be a so-called metal-insulator field-effect transistor (MISFET). For example, as the transistor 280 shown in FIG. 10B, the active layer 262 may be composed of a laminate of a first active layer 262-1 including a p-type gallium nitride layer and a second active layer 262-2 located over the first active layer 262-1 and including i-type or n-type gallium nitride without forming the electron-supplying layer 264. The second active layer 262-2 may be formed so as to be divided into a portion between the first active layer 262-1 and the first terminal 266 and a portion between the first active layer 262-1 and the second terminal 268 so as to respectively form a source region and a drain region over the first active layer 262-1.

In the transistor 280, the buffer layer 260, the gate insulating film 270, the gate electrode 272, the first terminal 266, and the second terminal 268 as well as the active layer 262 determining the characteristics of the transistor 280 can also be formed by a sputtering method using the aforementioned sputtering apparatus 100. Therefore, since the sputtering target 160 can always be maintained in an ideal condition, the transistors 280 with excellent characteristics can be mass-produced without affecting the tact time.

Although an explanation is omitted, the aforementioned sputtering apparatus 100 and the evaluating method of the sputtering target 160 using the sputtering apparatus 100 can be used not only for fabricating semiconductor devices described above, but also for forming a variety of configurations such as wirings, terminals, capacitance elements, and electrodes necessary for driving semiconductor devices.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A sputtering apparatus comprising:
a target holder for holding a sputtering target;
at least one light source for irradiating the sputtering target held by the target holder with light; and
at least one detector,
wherein the at least one detector is arranged to detect at least one of reflected light and scattered light of the light at a surface of the sputtering target.

2. The sputtering apparatus according to claim 1,
wherein the at least one detector includes a first detector arranged to detect the reflected light and a second detector to detect the scattered light.

3. The sputtering apparatus according to claim 1,
wherein the at least one detector is arranged so that an incident angle of the light to the sputtering target is equal to or larger than 60° and equal to or smaller than 85°.

4. The sputtering apparatus according to claim 1, further comprising:
a substrate holder; and
a shutter between the substrate holder and the target holder,
wherein the at least one light source is arranged to irradiate the sputtering target with the light through a gap between the target holder and the shutter, and
the at least one detector is arranged to detect the reflected light through the gap.

5. The sputtering apparatus according to claim 1, further comprising:
a substrate holder; and
a shutter located between the substrate holder and the target holder and having a through hole,
wherein the at least one light source is arranged to irradiate the sputtering target with the light through a gap between the target holder and the shutter, and
the at least one detector is arranged to detect the scattered light through the through hole.

6. The sputtering apparatus according to claim 1,
wherein the at least one light source is selected from a xenon lamp, a halogen lamp, a white-emissive diode, and a combination of a red-emissive diode, a green-emissive diode, and a blue-emissive diode.

7. The sputtering apparatus according to claim 1,
wherein the at least one light source includes at least two of a red-emissive diode, a green-emissive diode, and a blue-emissive diode.

8. The sputtering apparatus according to claim 7,
wherein at least one of the red-emissive diode, the green-emissive diode, and the blue-emissive diode is configured to emit a laser light.

9. The sputtering apparatus according to claim 1, further comprising a chamber accommodating the target holder, the at least one light source, and the at least one detector.

10. The sputtering apparatus according to claim 1, further comprising a chamber accommodating the target holder,
wherein at least one of the at least one light source and the at least one detector is arranged outside the chamber.

11. An evaluation method of a sputtering target comprising:
irradiating the sputtering target with light from at least one light source; and
detecting at least reflected light and scattered light at a surface of the sputtering target.

12. The evaluation method according to claim 11, comprising detecting the reflected light and the scattered light.

13. The evaluation method according to claim 11,
wherein the sputtering target is irradiated with the light at an incident angle equal to or larger than 60° and equal to or smaller than 85°.

14. The evaluation method according to claim 11,
wherein the sputtering target is irradiated with the light through a gap between the sputtering target and a shutter overlapping the sputtering target, and
the reflected light is detected through the gap.

15. The evaluation method according to claim 11,
wherein the sputtering target is irradiated with the light through a gap between the sputtering target and a shutter overlapping the sputtering target, and
the scattered light is detected through a through hole provided to the shutter.

16. The evaluation method according to claim 11,
wherein the at least one light source is selected from a xenon lamp, a halogen lamp, a white-emissive diode, and a combination of a red-emissive diode, a green-emissive diode, and a blue-emissive diode.

17. The evaluation method according to claim 11,
wherein the at least one light source includes at least two of a red-emissive diode, a green-emissive diode, and a blue-emissive diode.

18. The evaluation method according to claim 17,
wherein at least one of the red-emissive diode, the green-emissive diode, and the blue-emissive diode is configured to emit a laser light.

19. The evaluation method according to claim 11,
wherein the at least one light source is arranged in a chamber accommodating the sputtering target, and
at least one of the reflected light and the scattered light is detected in the chamber.

20. The evaluation method according to claim 11,
wherein the at least one light source is arranged outside a chamber accommodating the sputtering target, and
at least one of the reflected light and the scattered light is detected outside the chamber.
